(19) United States
(12) Patent Application Publication
(10) Pub. No.: US 2010/0098519 A1
(43) Pub. Date: Apr. 22, 2010

(54) SUPPORT FOR A SEMICONDUCTOR WAFER IN A HIGH TEMPERATURE ENVIRONMENT

(75) Inventors: Larry Wayne Shive, St. Charles, MO (US); Brian Lawrence Gilmore, Foristell, MO (US); Timothy John Snyder, Florissant, MO (US)

Correspondence Address: SENNIGER POWERS LLP, 100 NORTH BROADWAY, 17TH FLOOR, ST LOUIS, MO, 63102, US

(73) Assignee: MEMC ELECTRONIC MATERIALS, INC., St. Peters, MO (US)

(21) Appl. No.: 12/253,664

(22) Filed: Oct. 17, 2008

(51) Int. Cl. H01L 21/687

(52) U.S. Cl. 414/587; 414/586

(57) ABSTRACT

A wafer support for supporting a semiconductor wafer during a process including varied temperature. The wafer support includes a body having a top surface adapted to receive the semiconductor wafer so a portion of the top surface supports the wafer. The top surface has a recessed area including an inclined surface rising from a bottom of the recessed area. The inclined surface has an incline angle that is no more than about ten degrees.

### BACKGROUND

The present invention relates generally to apparatus for supporting a semiconductor wafer in a high temperature environment, and more particularly to such apparatus and methods adapted to limit damage to the semiconductor wafer.

Semiconductor wafers commonly undergo high temperature heat treatment (e.g., annealing) to achieve certain desirable characteristics. For example, high temperature heat treatment may be used to create a defect free layer of silicon on the semiconductor wafers. The high temperature annealing process is typically carried out in a vertical furnace which subjects the wafers to temperatures of at least about 1100 degrees centigrade, most commonly between about 1200 degrees centigrade and about 1300 degrees centigrade. Semiconductor wafers may also be subjected to various other high temperature heat treatment processes, e.g., rapid thermal processing (RTP), to achieve various wafer characteristics that may be desired.

Semiconductor wafers become more plastic at the high temperatures associated with high temperature heat treatment. For example, silicon wafers become more plastic at temperatures above 750 degrees centigrade and especially at temperatures above 1100 degrees centigrade. If the semiconductor wafers are not adequately supported during heat treatment, the wafers may undergo slip due to gravitational and thermal stresses. As is well known in the art, slip may introduce contaminants into the device areas of the wafers. Moreover, excessive slip may cause the wafers to plastically deform, leading to production problems, such as photolithography overlay failures causing yield losses in device manufacture.

The wafer support is usually constructed of a different material than the semiconductor wafer. For example, wafer supports are often constructed of silicon carbide (SiC) because this material remains relatively strong when subjected to the high temperatures encountered during high temperature heat treatment. However, there can be a mismatch in the coefficients of thermal expansion if the wafer support is made of a different material than the semiconductor wafer. Thermal mismatch may cause the wafer to slide on surfaces of the wafer support during heating and cooling.

FIGS. 1 and 2 illustrate a prior art wafer support is used to support semiconductor wafers in high temperature environments. This prior art wafer support is constructed of SiC and has an open C-shaped configuration. This configuration allows wafers to be robotically loaded and unloaded from the wafer support. The wafer support has a top surface that engages the wafer to support the wafer. There is an arcuate groove about 0.2 millimeter (mm) deep and about 30 mm wide in the top surface of the wafer support. The purpose of this groove is to prevent the wafer from floating on top of the wafer support during loading and also to prevent the wafer from sticking to the wafer support during unloading. The inner and outer edge margins of the groove are often broken edges and the shape of these edges cannot be finely controlled by machining due to difficulties in machining SiC. The inventors have observed a tendency for the edges of the groove of the prior art wafer support to damage the semiconductor wafer. Damage inflicted on the wafer by the groove reduces wafer yield.

### SUMMARY

In one aspect, the present invention includes a wafer support for supporting a semiconductor wafer during a process including varied temperature. The wafer support comprises a body having a top surface adapted to receive the semiconductor wafer so a portion of the top surface supports the wafer. The top surface has a recessed area including an inclined surface rising from a bottom of the recessed area. The inclined surface has an incline angle that is no more than about ten degrees.

In another aspect, the present invention includes a wafer support for supporting a semiconductor wafer in a heat treatment process. The wafer support comprises a body having a top surface adapted to engage the semiconductor wafer with at least a portion of the top surface supporting the wafer. The top surface has an outer edge and a recessed area having a inner limit and an outer limit. The inner and outer limits are substantially free of broken edges inside the outer edge of the top surface.

In still another aspect, the present invention includes a wafer support for supporting a semiconductor wafer during a process including varied temperature. The wafer support comprises a body having a top surface adapted to receive the semiconductor wafer so a portion of the top surface supports the wafer. The top surface has a recessed area including an inclined outer margin rising from a bottom of the recessed area. The inclined outer margin has an incline angle that is no more than about five degrees.

In yet another aspect, the present invention includes a wafer support for supporting a semiconductor wafer during a process including varied temperature. The wafer support comprises a body having a top surface adapted to receive the semiconductor wafer so a portion of the top surface supports the wafer. The top surface has a recessed area and a rounded ridge extending around the body inside the recessed area. The recessed area includes an inner margin formed by at least a portion of the rounded ridge. The inner margin has a maximum incline angle that is no more than about ten degrees.

The present invention also includes a wafer support for supporting a semiconductor wafer during a process including varied temperature. The wafer support comprises a body having a top surface adapted to receive the semiconductor wafer so a portion of the top surface supports the wafer. The top surface has a constant slope between a higher outer edge and a lower inner edge.

In another aspect, the present invention includes a wafer support for supporting a semiconductor wafer during a process including varied temperature. The wafer support comprises a body having a top surface adapted to receive the semiconductor wafer so a portion of the top surface supports the wafer. The top surface has a slope at a higher outer edge and a substantially equal slope at a lower inner edge.

Other objects and features will be in part apparent and in part pointed out hereinafter.

### BRIEF DESCRIPTION OF THE DRAWINGS

FIG. 1 is a plan view of a prior art wafer support;

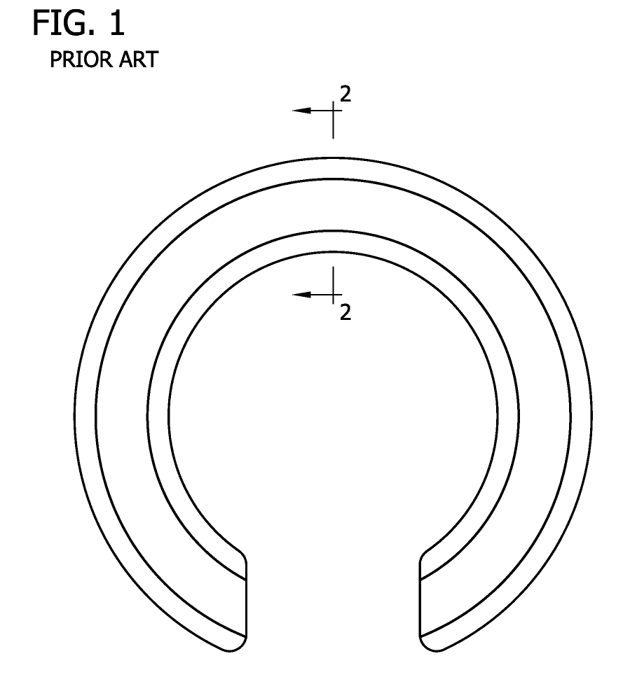

FIG. 2 is an enlarged section of a portion of the prior art wafer support taken in a plane including line 2-2 on FIG. 1;

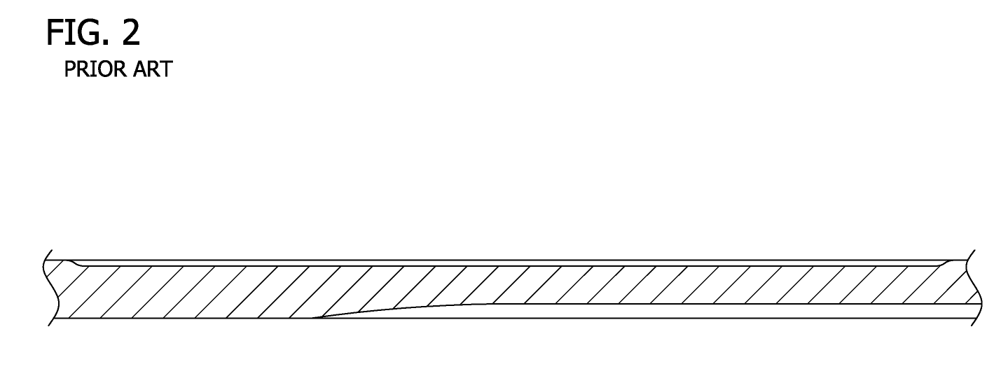

FIG. 3 is a plan view of a first embodiment of a the wafer support of the present invention;

FIG. 4 is an enlarged section of a portion of the wafer support of the first embodiment taken in a plane including line 4-4 of FIG. 3;

FIG. 5 is a plan view of a second embodiment of a the wafer support of the present invention; and

FIG. 6 is an enlarged section of a portion of the wafer support of the second embodiment taken in a plane including line 6-6 of FIG. 5.

Corresponding reference characters indicate corresponding parts throughout the drawings.

### DETAILED DESCRIPTION

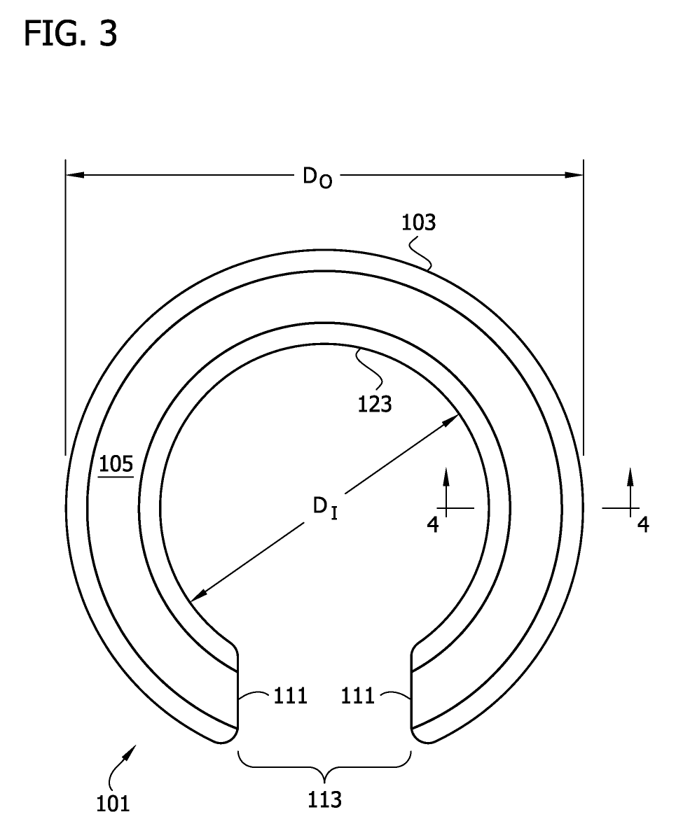

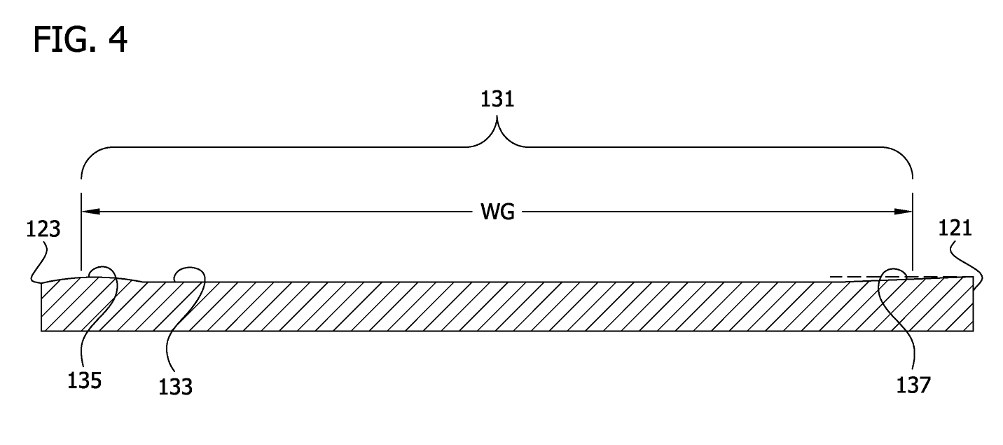

Referring to FIGS. 3 and 4, a first embodiment of a wafer support of the present invention, generally designated 101, comprises a body 103 adapted to engage a semiconductor wafer (e.g., a silicon wafer, not shown) and support the wafer in a high temperature environment. For example, the wafer support 101 is suitable for use in a process in which the wafer is annealed at a high temperature in a furnace. The wafer support 101 is also suitable for supporting the wafer as it is heated from a relatively low temperature to a relatively high temperature and/or cooled from the relatively high temperature to the relatively lower temperature.

In this embodiment, the body 103 has a C-shaped configuration. As illustrated in FIG. 3, the body 103 is a generally circular ring segment. A top surface 105 of the body 103 is generally flat (except as noted) for engaging a back of the substantially flat semiconductor wafer. The wafer support 101 can have various orientations when not in use and the top surface 105 may not be the top of the body 103, depending on the orientation of the wafer support at the time. For convenience, the surface facing up in use is referred to as the top surface 105. The wafer support 101 is capable of withstanding an environment having a temperature in excess of 1050 degrees centigrade (e.g., about 1200 degrees centigrade). For instance, the wafer support 101 may be constructed of silicon carbide (SiC). In one embodiment, the body 103 is a unitary body as illustrated in FIGS. 3 and 4.

The body 103 has opposing ends 111 defining an opening 113 in one sector of the body. The ends 111 are spaced from one another by a distance sufficient to provide clearance for a robotic arm (not shown) to extend between the ends to access an internal space that is partially enclosed by the C-shaped body 103 when the robot automatically loads and unloads the wafer from the wafer support 101. For example, the opposing ends 111 of the illustrated embodiment are spaced from one another by a distance D in a range from about 50 millimeters (mm) to about 150 mm. The top surface 105 of the wafer support 101 has an outer edge 121 having a diameter DO in a range from about 300 mm to about 310 mm. In one embodiment, the outer edge 121 has a diameter of more than about 300 mm (e.g., about 360 mm) for processing 300 mm diameter wafers. The top surface 105 of the wafer support 101 has an inner edge 123 having a diameter Di in a range from about 190 mm to about 210 mm. Further, the body 103 has a width W in a range from about 45 mm to about 60 mm.

The top surface 105 of the wafer support 101 includes a broad arcuate groove 131. This groove 131 reduces the potential for the wafer to float above the top surface 105 of the wafer support 101 as it is loaded. The groove 131 also reduces the potential for the wafer to stick to the wafer support 101 during unloading. In the embodiment illustrated in FIGS. 3 and 4, the groove 131 extends from one end 111 of the wafer support 101 to the other along an arc having a center that is coincident with the center of the circular body 103. Thus, in this embodiment, the arcuate groove 131 is concentric with the C-shaped body 103 of the wafer support 101. As illustrated, the groove 131 extends continuously along the body 103 and has a substantially uniform width WG. The groove width WG can vary within the scope of the invention. For example, in one embodiment, the groove 131 has a width WG in a range from about 15 mm to about 50 mm. It is envisioned that in some embodiments, the groove width WG can vary along its length and/or the groove 131 can be non-concentric with respect to the body 103.

As shown in FIG. 4, the groove 131 has a generally planar bottom 133 extending between a crowned ridge 135 and an inclined outer margin 137. The crowned ridge 135 forms a machined surface upon which the wafer rests. Because the ridge 135 is machined, it provides a smooth surface that reduces potential for damaging the back of the wafer. Although the ridge 135 may have other roughnesses without departing from the scope of the present invention, in one embodiment, the ridge 135 has a surface roughness of less than about 2 micrometers (μm) roughness average (Ra). Although the ridge 135 may have other smooth cross-sectional shapes without departing from the scope of the present invention, in one embodiment the cross section has a rounded shape. In one particular embodiment, the ridge 135 has a cross section that is a segment of a circle having a maximum incline angle of no more than about 10°. In some embodiments, the ridge 135 has a cross section that is a segment of a circle having a maximum incline angle of no more than about 5°. In still other embodiments, the ridge 135 has a cross section that is a segment of a circle having a maximum incline angle of no more than about 2.5°. Further, in some embodiments, the ridge 135 rises about 0.2 mm above the bottom 133 of the groove. In the illustrated embodiment, the elevations of the inner ridge 135 and the outer edge 121 are about equal.

In some embodiments, the inclined outer margin 137 has a generally constant slope from the bottom 133 of the groove 131 to the outer edge 121 of the body 103. In one embodiment, the inclined outer margin 137 slopes at an incline angle of about 5°. In some embodiments, the margin 137 slopes at an incline angle of about 2.5°. In still other embodiments, the margin 137 slopes at an incline angle of about 1°. In some embodiments the margin 137 extends to the outer edge 121 of the top surface 105. Although the outer margin 137 may have other widths without departing from the scope of the present invention, in some embodiments the inclined outer margin has a width WO of about 2 mm.

In some embodiments, the body 103 can optionally include multiple pieces and may be configured differently (e.g., as a round plate, closed ring, or other shape that does not have any opening for use by a robot arm) within the scope of the invention. Likewise, the body 103 can be made from materials other than SiC within the scope of the invention.

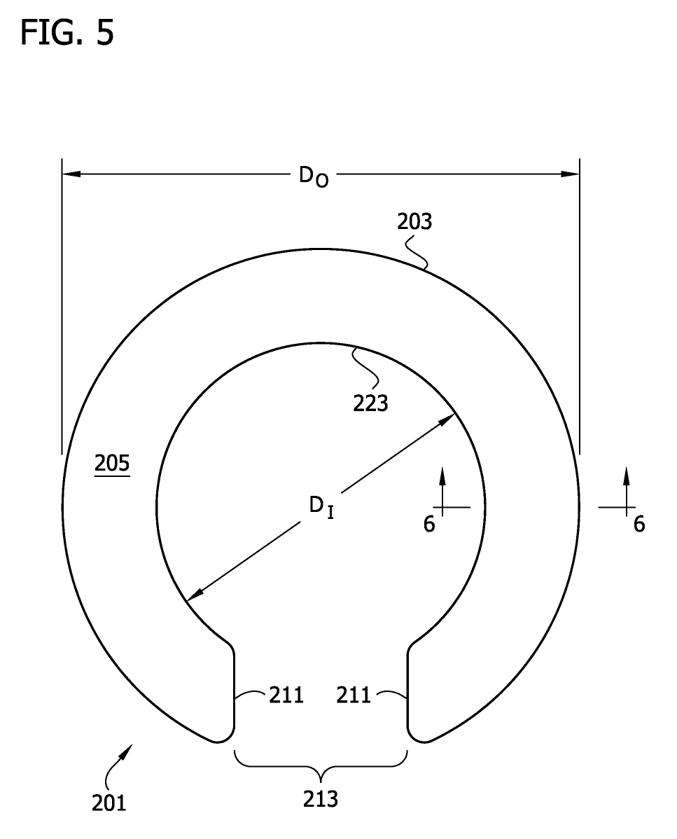

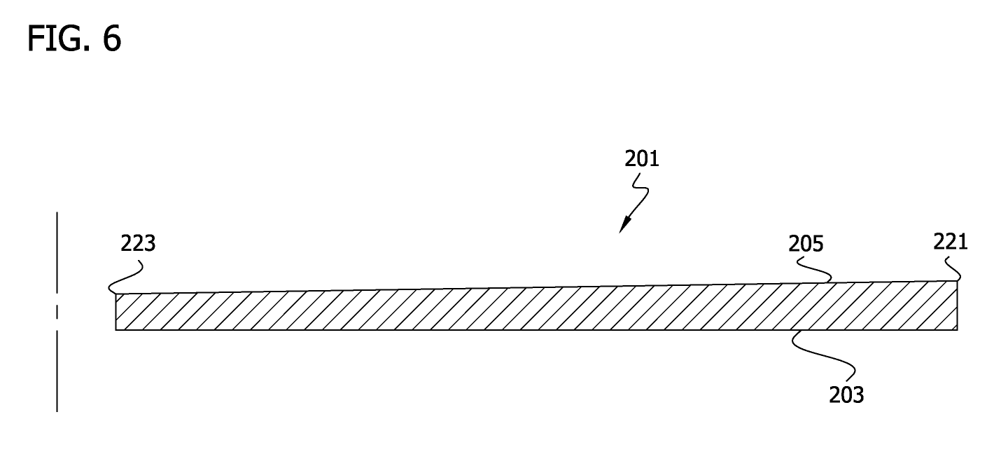

Referring to FIGS. 5 and 6, a second embodiment of a wafer support of the present invention, generally designated 201, comprises a body 203 adapted to engage a semiconductor wafer (e.g., a silicon wafer, not shown) and support the wafer in a high temperature environment. In this embodiment, the body 203 has a C-shaped configuration. As illustrated in FIG. 5, the body 203 is a generally circular ring segment. A top surface 205 of the body 203 is generally conical for engaging an outer edge of a back of the substantially flat semiconductor wafer.

The body 203 has opposing ends 211 defining an opening 213 in one sector of the body. The ends 211 are spaced from one another by a distance sufficient to provide clearance for a robotic arm (not shown) to move between the ends to access an internal space that is partially enclosed by the C-shaped body 203 when the robot automatically loads and unloads the wafer from the wafer support 201. For example, the opposing ends 211 of the illustrated embodiment are spaced from one another by a distance D in a range similar to the support of the first embodiment. The top surface 205 of the wafer support 201 has an outer edge 221 having a diameter DO in a range similar to the support of the first embodiment. In one embodiment, the outer edge 221 has a diameter of more than about 300 mm (e.g., about 360 mm) for processing 300 mm diameter wafers. The top surface 205 of the wafer support 201 has an inner edge 223 having a diameter DI in a range similar to the support of the first embodiment. Further, the body 203 has a width W in a range similar to the support of the first embodiment.

In some embodiments, the top surface 205 has a generally constant slope from the inner edge 223 to the outer edge 221 of the body 203. It is envisioned in some embodiments the slope may vary radially and/or circumferentially without departing from the scope of the present invention. In one embodiment, the top surface 205 slopes at an incline angle of about 5°. In some embodiments, the top surface 205 slopes at an incline angle of about 2.5°. In still other embodiments, the top surface 205 slopes at an incline angle of about 1°.

In some embodiments, the body 201 can optionally include multiple pieces and may be configured differently (e.g., as a round plate, closed ring, or other shape that does not have any opening for use by a robot arm) within the scope of the invention. Likewise, the body 201 can be made from materials other than SiC within the scope of the invention.

When introducing elements of the present invention or the preferred embodiments thereof, the articles “a”, “an”, “the”, and “said” are intended to mean that there are one or more of the elements. The terms “comprising”, “including”, and “having” are intended to be inclusive and mean that there may be additional elements other than the listed elements.

In view of the above, it will be seen that the several objects of the invention are achieved and other advantageous results attained.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A wafer support for supporting a semiconductor wafer during a process including varied temperature, the wafer support comprising a body having a top surface adapted to receive the semiconductor wafer so a portion of the top surface supports the wafer, said top surface having a recessed area including an inclined surface rising from a bottom of the recessed area, the inclined surface having an incline angle that is no more than about ten degrees.

2. A wafer supper as set forth in claim 1 wherein the inclined surface forms at least a portion of an outer margin of the recessed area.

3. A wafer supper as set forth in claim 2 wherein the inclined surface having an incline angle that is no more than about five degrees.

4. A wafer supper as set forth in claim 3 wherein the inclined surface having an incline angle that is no more than about 2.5 degrees.

5. A wafer supper as set forth in claim 4 wherein the inclined surface having an incline angle that is no more than about one degree.

6. A wafer supper as set forth in claim 1 wherein the inclined surface forms at least a portion of an inner margin of the recessed area.

7. A wafer supper as set forth in claim 6 wherein the inclined surface having an incline angle that is no more than about five degrees.

8. A wafer supper as set forth in claim 7 wherein the inclined surface having an incline angle that is no more than about 2.5 degrees.

9. A wafer support as set forth in claim 1 wherein the upper surface includes a rounded ridge at least a portion of which forms a margin of the recessed area.

10. A wafer support as set forth in claim 9 wherein the rounded ridge forms an inner margin of the recessed area.

11. A wafer support as set forth in claim 10 wherein the rounded ridge has a surface roughness of less than about 2 μm Ra.

12. A wafer support as set forth in claim 10 wherein the rounded ridge is substantially continuous around an inner margin of the recessed area.

13. A wafer support as set forth in claim 10 wherein the rounded ridge has a height of no more than about 0.2 mm above a bottom of the recessed area.

14. A wafer support as set forth in claim 1 wherein an outer edge of the top surface has a height of no more than about 0.2 mm above a bottom of the recessed area.

15. A wafer support as set forth in claim 1 wherein the recessed portion has a substantially uniform width.

16. A wafer support as set forth in claim 1 wherein the body comprises a material that retains stiffness sufficient to support the wafer at a temperature of at least about 1050 degrees centigrade.

17. A wafer support as set forth in claim 15 wherein the body comprises silicon carbide.

18. A wafer support as set forth in claim 1 wherein the recessed area comprises an arcuate groove.

19. A wafer support for supporting a semiconductor wafer in a heat treatment process, the wafer support comprising a body having a top surface adapted to engage the semiconductor wafer with at least a portion of said top surface supporting the wafer, said top surface having an outer edge and a recessed area having a inner limit and an outer limit, the inner and outer limits being substantially free from broken edges inside of the outer edge of the top surface.

20. A wafer support for supporting a semiconductor wafer during a process including varied temperature, the wafer support comprising a body having a top surface adapted to receive the semiconductor wafer so a portion of the top surface supports the wafer, said top surface having a recessed area including an inclined outer margin rising from a bottom of the recessed area, the inclined outer margin having an incline angle that is no more than about five degrees.

21. A wafer support for supporting a semiconductor wafer during a process including varied temperature, the wafer support comprising a body having a top surface adapted to receive the semiconductor wafer so a portion of the top surface supports the wafer, said top surface having a recessed area and a rounded ridge extending around the body inside the recessed area, the recessed area including an inner margin formed by at least a portion of the rounded ridge, said inner margin having a maximum incline angle that is no more than about ten degrees.

22. A wafer support for supporting a semiconductor wafer during a process including varied temperature, the wafer support comprising a body having a top surface adapted to receive the semiconductor wafer so a portion of the top surface supports the wafer, said top surface having a constant slope between a higher outer edge and a lower inner edge.

23. A wafer support for supporting a semiconductor wafer during a process including varied temperature, the wafer support comprising a body having a top surface adapted to receive the semiconductor wafer so a portion of the top surface supports the wafer, said top surface having a slope at a higher outer edge and a substantially equal slope at a lower inner edge.
